(19) United States
(12) Patent Application Publication
(10) Pub. No.: US 2026/0206250 A1
(43) Pub. Date: Jul. 16, 2026

(54) RADIO FREQUENCY HIGH ELECTRON MOBILITY TRANSISTORS

(71) Applicant: INDIAN INSTITUTE OF SCIENCE, Bangalore (IN)

(72) Inventors: Mohammad Ateeb MUNSHI, Bangalore (IN); Mayank SHRIVASTAVA, Bangalore (IN)

(21) Appl. No.: 19/447,771

(22) Filed: Jan. 13, 2026

(30) Foreign Application Priority Data
Jan. 14, 2025 (IN) 202541003074

(51) Int. Cl. H10D 30/47; H10D 62/10; H10D 62/824; H10D 64/00; H10D 89/60; H10W 74/10; H10W 74/40

(52) U.S. Cl. CPC H10D 30/475; H10D 62/102; H10D 62/824; H10D 64/111; H10D 89/601; H10W 74/137; H10W 74/481

(57) ABSTRACT

The present disclosure relates to a Radio Frequency (RF) High-Electron-Mobility Transistor (HEMT) (200). The RF HEMT (200) includes a Gallium Nitride (GaN) layer (202) formed on a substrate (214). The RF HEMT (200) includes a source (204a), a drain (204b), and a gate (204c) configured on the GaN layer (202). The RF HEMT (200) includes a passivation layer (206) including at least a p-type semiconductor (206a) disposed over the GaN layer (202). The passivation layer (206) is configured to distribute channel electric field in a gate-drain access region of the RF HEMT (200), to reduce self-heating effect in the RF HEMT (200). Further, the passivation layer (206) enhances performance, reliability, and signal characteristics of the RF HEMT (200), minimizes current collapse during a high-frequency operation, and increases a breakdown voltage of the RF HEMT (200).

### DISCLAIMER

Portions of this patent document may contain material that may be subject to Copyright or Trademark protection. The owner has no objection to the facsimile reproduction by anyone of the patent document or the patent disclosure, as it appears in the Patent and Trademark Office file or records, but otherwise reserves all copyright rights and trademarks whatsoever. All copyrights and trademarks are owned by Indian Institute of Science, Bangalore.

### TECHNICAL FIELD

The present disclosure relates generally to the field of Radio Frequency (RF) High-Electron-Mobility Transistors (HEMTs). Specifically, the present disclosure pertains to advanced passivation and gate-dielectric techniques to enhance performance, reliability, and thermal management of Gallium Nitride (GaN)-based RF HEMTs, particularly those implemented on Silicon (Si) substrates.

### BACKGROUND

The background information provided hereunder is instructive for understanding the present disclosure but does not necessarily constitute prior art with respect to any of the embodiments of the present disclosure described herein.

Gallium Nitride (GaN)-based High-Electron-Mobility Transistors (HEMTs) are emerging for high-power and high-frequency application. FIG. 1 illustrates a cross-sectional view of a conventional GaN RF Metal-Insulator-Semiconductor (MIS)-HEMT (100) with a standard passivation layer.

In RF applications, power amplifiers with large gain, high output power, and high power-added efficiency (PAE) are highly desirable. Traditionally, Silicon Carbide (SiC) has been a preferred substrate for the GaN RF HEMTs due to absence of native GaN substrates. However, the commercialization of the GaN RF HEMTs remains constrained due to high cost of the SiC, which poses a significant challenge for high-volume, cost-sensitive applications. Furthermore, the SiC substrates are typically limited to smaller wafer sizes (4–6 inches) compared to silicon wafers, which are available in sizes up to 12 inches. This limitation affects scalability and increases the cost per chip for SiC-based devices.

GaN-on-Silicon (GaN-on-Si) technology has emerged as a cost-effective alternative for commercializing the GaN RF HEMTs, leveraging a lower cost of silicon and its well-established process technology. However, the GaN-on-Si RF HEMTs face significant challenges, including severe trapping effects and self-heating issues. These issues arise from the higher lattice mismatch between the GaN and the silicon, as well as the poor thermal conductivity of silicon, which restrict the dynamic and large-signal performance of these devices. Trapping effects lead to current collapse (CC), reducing the maximum current in the GaN HEMTs and degrading their RF performance. Similarly, self-heating exacerbates RF performance degradation by increasing lattice scattering and reducing carrier mobility.

Recent research efforts have focused on improving buffer and surface characteristics to reduce trap density and limit the CC. However, the role of the channel electric field in influencing CC behavior is often overlooked. Although traps are significant contributors, the primary cause of the CC is the high channel electric field. Additionally, various strategies have been employed to minimize self-heating in the GaN HEMTs, such as microfluidic cooling, substrate thinning, and the use of diamond substrates. While these strategies are effective to some extent, these approaches are costly and/or involve complex processing steps, and they do not directly address the heating issue within the GaN HEMTs.

Therefore, there is, a need for an improved RF HEMTs to at least overcome the above-mentioned deficiencies.

### OBJECTS OF THE PRESENT DISCLOSURE

Some of the objects of the present disclosure which are sought to be achieved by at least one embodiment herein described are enlisted hereunder.

An object of the present disclosure is to provide a p-type passivation layer for Gallium Nitride (GaN)-based Radio Frequency (RF) High-Electron-Mobility Transistors (HEMTs) for enhanced performance and improved device reliability.

An object of the present disclosure is to provide a p-type passivation layer that improves Direct Current (DC) characteristics, current collapse behavior, breakdown voltage, and large signal characteristics of the RF HEMTs.

An object of the present disclosure is to use a p-type semiconductor as passivation and gate-dielectric to reduce off-state leakage characteristics compared to conventional Silicon Nitride (SiN) passivation and gate dielectric.

Another object of the present disclosure is to provide a p-type passivation layer that suppresses self-heating considerably, enabling improved output power, gain, and power added efficiency.

Yet another object of the present disclosure is to provide a p-type passivation layer that efficiently distributes channel electric field in a gate-drain access region by suppressing an electric field peak near gate edge/field plate edge, which is a root cause of reliability issues in the RF HEMTs.

Other objects and advantages of the present disclosure will be more apparent from the following description, which is not intended to limit the scope of the present disclosure.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure relates to a Radio Frequency (RF) High-Electron-Mobility Transistor (HEMT) including a Gallium Nitride (GaN) layer formed on a substrate. The RF HEMT includes a source, a drain, and a gate configured on the GaN layer. Further, the RF HEMT includes a passivation layer including at least a p-type semiconductor disposed over the GaN layer. The passivation layer is configured to distribute channel electric field in a gate-drain access region of the RF HEMT, to reduce self-heating effect in the RF HEMT.

In an embodiment, the p-type semiconductor may be disposed overlapping or underlapping a contact of the source and the drain.

In an embodiment, the p-type semiconductor may be deposited directly as a gate dielectric over a barrier region or any other passivation layer. The barrier region may be formed over the substrate.

In an embodiment, the p-type semiconductor may be deposited only as a passivation material and not present under a contact of the gate.

In an embodiment, the p-type semiconductor may be deposited towards the gate-drain access region.

In an embodiment, the p-type semiconductor may be deposited under a contact of the gate or a field plate of the RF HEMT.

In an embodiment, the passivation layer may be configured to enhance performance and reliability of the RF HEMT by distributing the channel electric field in the gate-drain access region.

In an embodiment, the passivation layer may be configured to enhance signal characteristics of the RF HEMT due to the reduction in the self-heating effect in the RF HEMT.

In an embodiment, the passivation layer may be configured to minimize current collapse during a high-frequency operation, and increase a breakdown voltage of the RF HEMT.

In an embodiment, the p-type semiconductor may be any or a combination of a nickel oxide, a p-GaN, a copper oxide, and an aluminium titanium oxide.

In an embodiment, the RF HEMT may be manufactured with or without a buffer region over the substrate.

In an embodiment, the buffer region may be formed of at least one type of a carbon-doped buffer, an iron-doped buffer, or a carbon and iron co-doped buffer.

In an embodiment, the RF HEMT may be configured with at least one of one or more barriers and one or more back barriers. The one or more barriers may be formed of at least one of Aluminum Nitride (AlN), graded Aluminum Gallium Nitride (AlGaN), and Gallium Nitride (GaN) cap.

In an embodiment, the passivation layer may be configured with any gradient and stoichiometry based on a requirement.

### BRIEF DESCRIPTION OF DRAWINGS

The accompanying drawings, which are incorporated herein, and constitute a part of this disclosure, illustrate exemplary embodiments of the disclosed methods and systems which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components, or circuitry commonly used to implement such components.

FIG. 1 illustrates a cross-sectional view of a conventional Gallium Nitride (GaN) Radio Frequency (RF) Metal-Insulator-Semiconductor High Electron Mobility Transistor (MIS-HEMT) with a standard passivation layer.

FIGS. 2A-2F illustrate GaN RF HEMT structures, in accordance with an embodiment of the present disclosure.

FIGS. 3A and 3B illustrate graphical representations depicting transfer characteristics of devices R1 and R2 respectively, in accordance with an embodiment of the present disclosure.

FIG. 3C illustrates a graphical representation depicting a comparison of gate leakage characteristics of R1 and R2 devices, in accordance with an embodiment of the present disclosure.

FIGS. 4A-4C illustrate graphical representations depicting current collapse measurement using pulse IV setup of R1, R2, and R3 devices having a field plate length (LFP)of 400 nm, respectively, in accordance with an embodiment of the present disclosure.

FIGS. 5A and 5B illustrate an Electroluminescence (EL) micrograph of R1 and R2 device, respectively, in accordance with an embodiment of the present disclosure.

FIGS. 5C and 5D illustrate graphical representations depicting an average EL intensity comparison of R1 and R2 devices, and three terminal breakdown comparisons of the R1 and R2 devices, respectively, in accordance with an embodiment of the present disclosure.

FIGS. 6A-6C illustrate schematic representations depicting comparison of maximum temperature rise (ΔT) for R1, R2, and R3 samples, respectively, in accordance with an embodiment of the present disclosure.

FIGS. 7A-7B illustrate graphical representations depicting comparison of large signal characteristics at 10 GHz of R1 and R2 devices, respectively, in accordance with an embodiment of the present disclosure.

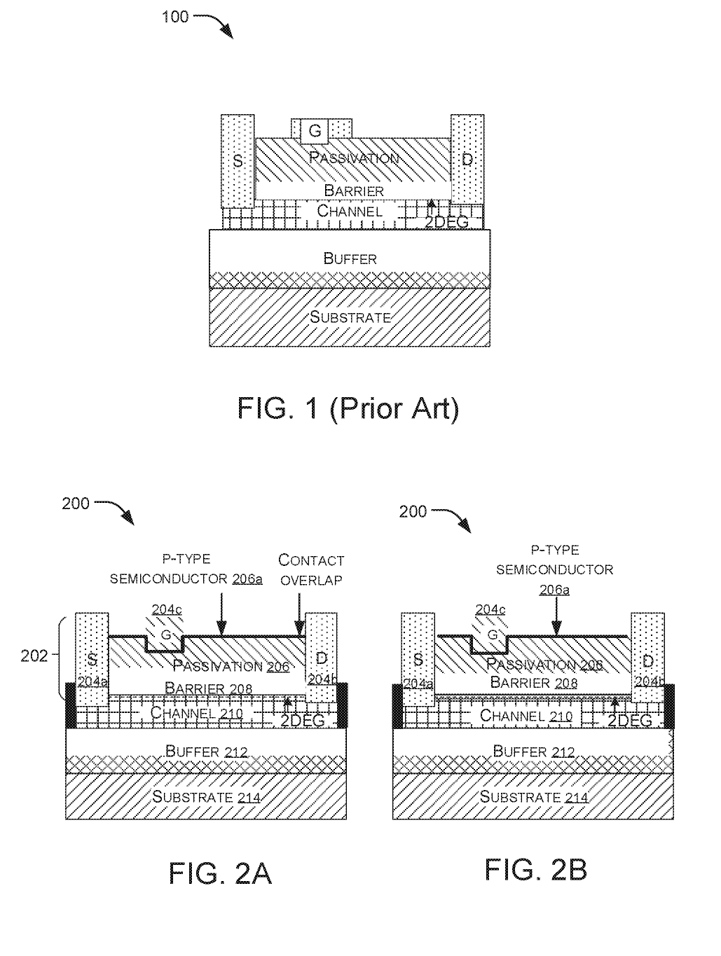

The foregoing shall be more apparent from the following more detailed description of the disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail to avoid obscuring the embodiments.

Also, it is noted that individual embodiments may be described as a process that is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive in a manner similar to the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an”, and “the” are intended to include the plural forms as well, unless the context indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present disclosure relates generally to the field of Radio Frequency (RF) High-Electron-Mobility Transistors (HEMTs). Specifically, the present disclosure pertains to advanced passivation and gate-dielectric techniques to enhance performance, reliability, and thermal management of Gallium Nitride (GaN)-based RF HEMTs, particularly those implemented on Silicon (Si) substrates.

The present disclosure relates to the RF HEMT including a Gallium Nitride (GaN) layer formed on a substrate. The RF HEMT includes a source, a drain, and a gate configured on the GaN layer. Further, the RF HEMT includes a passivation layer including at least a p-type semiconductor disposed over the GaN layer. The passivation layer is configured to distribute channel electric field in a gate-drain access region of the RF HEMT, to reduce self-heating effect in the RF HEMT. The passivation layer is configured to enhance performance and reliability of the RF HEMT by distributing the channel electric field in the gate-drain access region.

The passivation layer is configured to enhance signal characteristics of the RF HEMT due to the reduction in the self-heating effect in the RF HEMT. The passivation layer is configured to minimize current collapse during a high-frequency operation, and increase a breakdown voltage of the RF HEMT.

The RF HEMTs may be fabricated on a commercial grade GaN-on-Silicon (Si) and GaN-on-Silicon Carbide (SiC) wafer. The Silicon Nitride (SiN)-based GaN RF MIS-HEMT may be fabricated on Si/SiC substrate, and the GaN RF MIS-HEMT with a p-type oxide (AlₓTi₁-ₓO_{y}) on top of SiN as passivation and gate dielectric may be fabricated on the silicon substrate. AlₓTiₓO_{y} may be deposited using Atomic Layer Deposition (ALD) at 250° C for sample GaN RF MIS-HEMT with cyclic deposition of Al₂O₃ and TiO₂. The ratio of Al₂O₃:TiO₂ may be 1:12, giving a stoichiometry of Al₀.₄Ti₀.₆O, and the thickness may be 10 nm. After carrying out dielectric anneal for the GaN RF MIS-HEMT at 400°C for 1 minute in N2 ambient, AlₓTiₓO_{y} may be locally etched near the drain contacts.

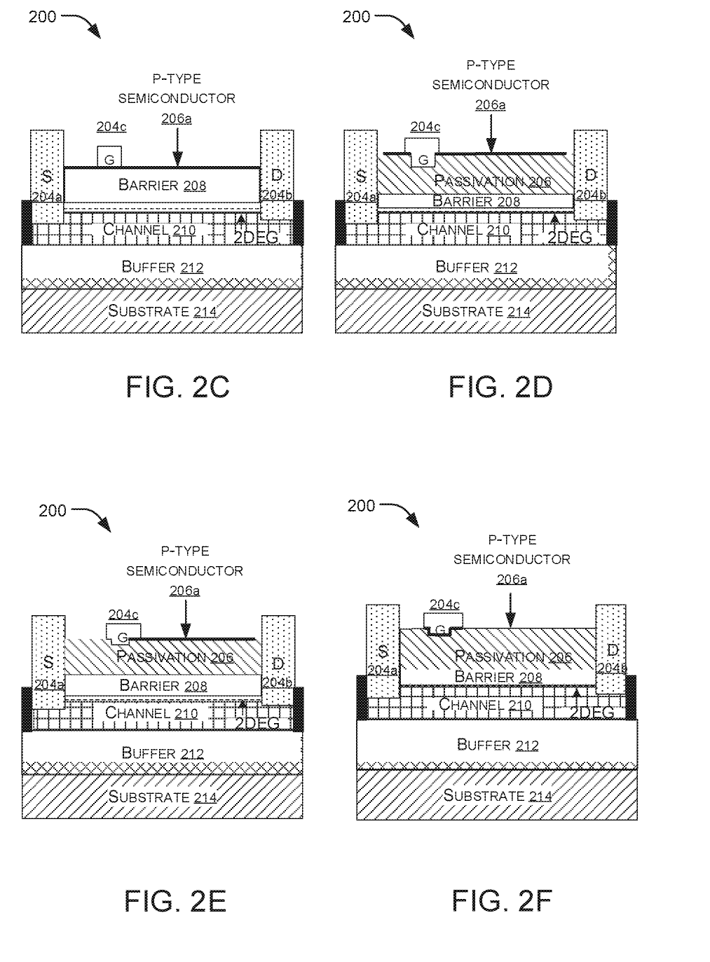

Various embodiments of the present disclosure will be explained in detail with reference to FIGS. 2A-7B.

FIGS. 2A-2F illustrate Gallium Nitride (GaN) Radio Frequency (RF) High Electron Mobility Transistor (MIS-HEMT) structures, in accordance with an embodiment of the present disclosure.

With reference to FIGS. 2A-2F, the RF HEMT (200) may include a GaN layer (202) formed on a substrate (214). The RF HEMT (200) may include a source (204a), a drain (204b), and a gate (204c) configured on the GaN layer (202). Further, the RF HEMT (200) may include a passivation layer (206) including at least a p-type semiconductor (206a) disposed over the GaN layer (202). The passivation layer (206) may be configured to distribute electric field of channel (210) (where majority of the current flows due to high electron mobility) in a gate-drain access region of the RF HEMT (200), to reduce self-heating effect in the RF HEMT (200).

The passivation layer (206) may be designed to spread the electric field more uniformly across the gate-drain access region. By reducing sharp field peaks, the passivation layer (206) may mitigate an intensity of the electric field near the gate edge or field plate edge. Further, self-heating occurs due to the generation of hot phonons in the RF HEMT (200), which arise from intense electric fields and lead to increased lattice vibrations. By evening out the electric field, the passivation layer (206) minimizes localized energy concentrations, reducing the generation of the hot phonons and the resultant heating effects.

In an embodiment, the passivation layer (206) may be configured to enhance performance and reliability of the RF HEMT (200) by distributing the channel electric field in the gate-drain access region. By managing the channel electric field, the RF HEMT (200) may experience less stress, which enhances its lifespan and maintains stable operation. In an embodiment, the passivation layer (206) may be configured to enhance signal characteristics of the RF HEMT (200) due to the reduction in the self-heating effect in the RF HEMT (200).

In an embodiment, the passivation layer (206) may be configured to minimize current collapse during a high-frequency operation, and increase a breakdown voltage of the RF HEMT (200). The current collapse is a phenomenon where the maximum current output is reduced due to trapping effects under high voltage or high-frequency conditions. The passivation layer (206) may be configured to mitigate these trapping effects by managing the electric field more effectively.

In an embodiment, the passivation layer (206) may be configured with any gradient and stoichiometry based on a requirement. The gradient may be referred to varying material properties (e.g., composition or thickness) across a layer to achieve specific performance goals, such as tailored electric field distribution. The stoichiometry may be referred to an exact chemical composition of the passivation material. By altering the stoichiometry (e.g., ratios of oxygen, aluminum, titanium in an oxide layer), the passivation layer (206) may be optimized for specific thermal, electrical, or mechanical properties.

In an embodiment, the p-type semiconductor (206a) may be disposed overlapping or underlapping a contact of the source (204a) and the drain (204b), as illustrated in FIG. 2A. In an embodiment, the p-type semiconductor (206a) may be deposited directly as a gate dielectric over a barrier region (208) or any other passivation layer, as illustrated in FIG. 2B and FIG. 2C. The barrier region (208) may be formed over the substrate (214).

In an embodiment, the p-type semiconductor (206a) may be deposited only as a passivation material and not present under a contact of the gate (204c), as illustrated in FIG. 2D. In an embodiment, the p-type semiconductor (206a) may be deposited towards the gate-drain access region, as illustrated in FIG. 2E. In an embodiment, the p-type semiconductor (206a) may be deposited under a contact of the gate (204c) or a field plate of the RF HEMT (200), as illustrated in FIG. 2F. In an embodiment, the p-type semiconductor (206a) may be any or a combination of a nickel oxide, a p-GaN, a copper oxide, and an aluminium titanium oxide. The p-type semiconductor (206a) may also boost the performance of the GaN HEMTs (200) on any substrate which includes, but not limited to, sapphire, SiC, diamond, and GaN.

In an embodiment, the RF HEMT (200) may be manufactured with or without a buffer region (212) over the substrate (214). The buffer region (212) may be formed of at least one type of a carbon-doped buffer, an iron-doped buffer, or a carbon and iron co-doped buffer.

In an embodiment, the RF HEMT (200) may be configured with at least one of one or more barriers (208) and one or more back barriers. The one or more barriers (208) may be formed of at least one of Aluminum Nitride (AlN), graded Aluminum Gallium Nitride (AlGaN), and Gallium Nitride (GaN) cap.

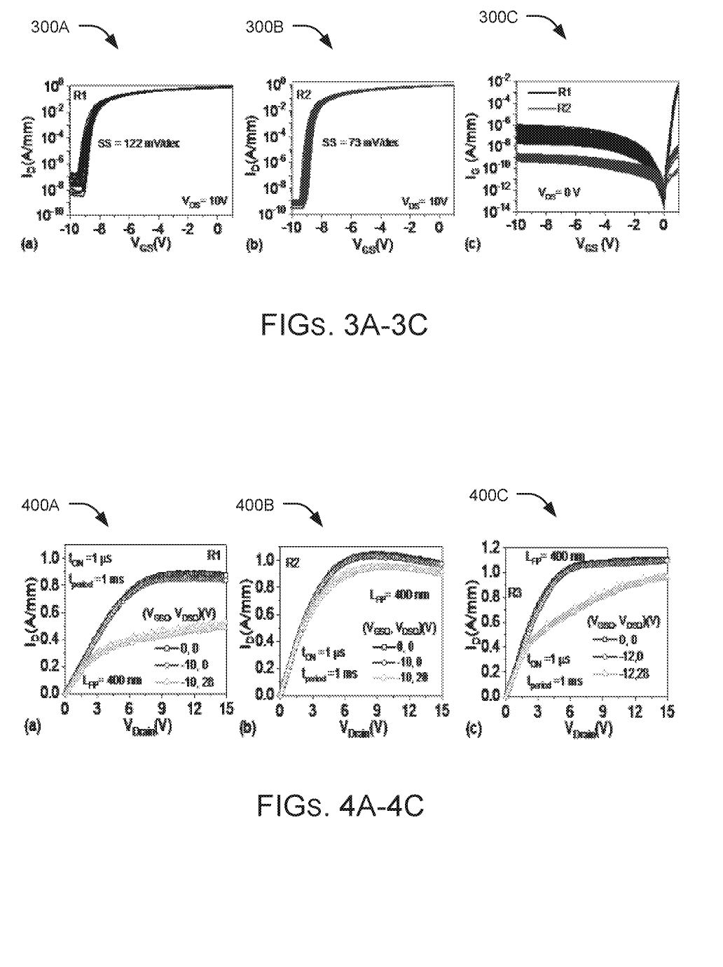

FIGS. 3A and 3B illustrate graphical representations (300A, 300B) depicting transfer characteristics of devices R1 and R2 respectively, in accordance with an embodiment of the present disclosure.

With reference to FIGS. 3A and 3B, the transfer characteristics of the device R1 and R2, respectively, are depicted. R2 devices show low off-state leakage by ~2 orders compared to the R1 device. Further, the R2 device shows an improved subthreshold slope SS of 73 mV/dec compared to the R1 device, which had SS = 122 mV/dec.

FIG. 3C illustrates a graphical representation (300C) depicting a comparison of gate leakage characteristics of the R1 and R2 devices, in accordance with an embodiment of the present disclosure.

With reference to FIG. 3C, a comparison of the gate leakage characteristics of the R1 and R2 devices, is depicted. The R2 device shows two orders lower off-state gate leakage and five orders lower on-state gate leakage compared to the R1 device. In addition, the variability in the R2 device is very low compared to the R1 device.

FIGS. 4A-4C illustrate graphical representations (400A-400C) depicting current collapse measurement using pulse IV setup of R1, R2, and R3 devices having a field plate length (LFP)of 400 nm, respectively, in accordance with an embodiment of the present disclosure.

The graphical representations (400A-400C) display the results or trends related to current collapse measurements. The current collapse measurement evaluates the degradation of current under pulsed biasing conditions due to trapping effects in the R1, R2, and R3 devices. A pulse IV setup is used for precise current collapse measurement by applying short voltage pulses, minimizing thermal effects and focusing on trapping behavior of the R1, R2, and R3 devices. The R1, R2, and R3 devices have a field plate length of 400 nm, ensuring a consistent parameter for comparison.

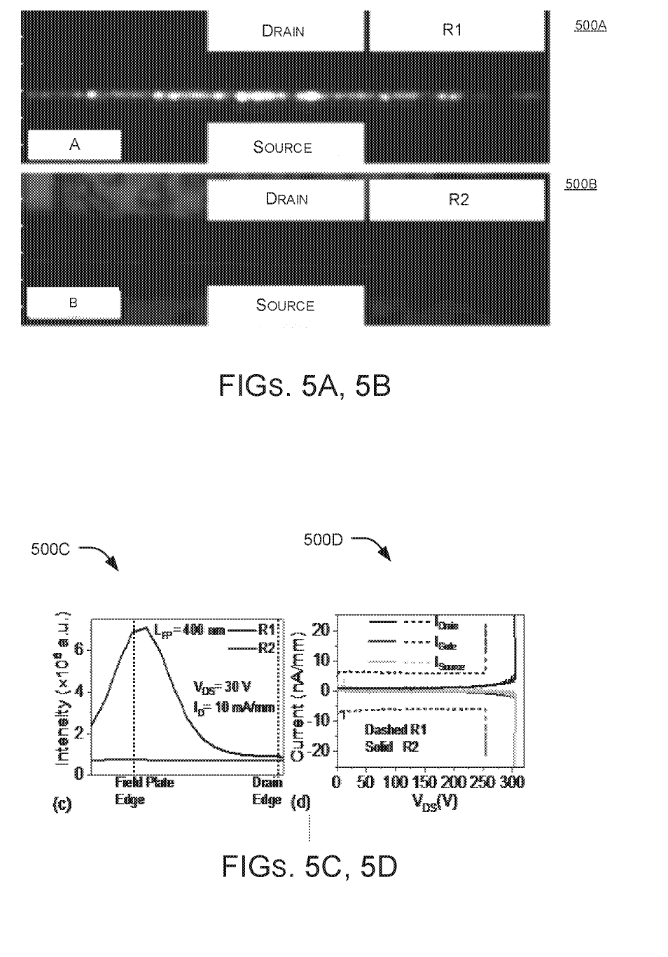

FIGS. 5A and 5B illustrate an Electroluminescence (EL) micrograph (500A, 500B) of the R1 and R2 devices, respectively, in accordance with an embodiment of the present disclosure.

With reference to FIGS. 5A and 5B, the EL micrograph (500A, 500B) of the R1 and R2 devices is depicted. The EL micrograph is an image that captures the light emitted from the R1 and R2 devices when the electric current is passed through the R1 and R2 devices or when the R1 and R2 devices are subjected to an electric field. The EL micrograph (500A, 500B) is obtained to analyze performance of the R1 and R2 devices, detect defects or hot spots in the R1 and R2 devices, and compare the behavior of the R1 and R2 devices.

FIGS. 5C and 5D illustrate graphical representations (500C, 500D) depicting an average EL intensity comparison of the R1 and R2 devices, and three terminal breakdown comparisons of the R1 and R2 devices, respectively, in accordance with an embodiment of the present disclosure.

FIG. 5C depicts the average EL intensity comparison of the R1 and R2 devices, respectively, for I_{D}= 10mA/mm and V_{DS}= 28 V, showing suppressed EL intensity for the R2 device. FIG. 5D depicts three terminal breakdown comparisons of the R1 and R2 devices, showing enhanced breakdown voltage for the R2 device.

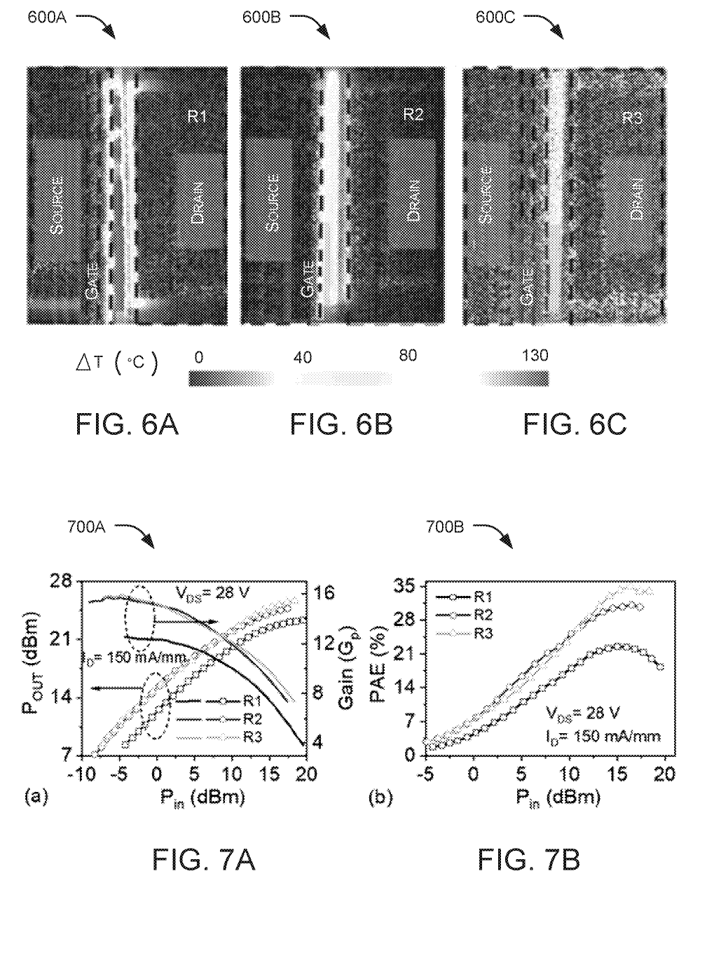

FIGS. 6A-6C illustrate schematic representations (600A-600C) depicting comparison of maximum temperature rise (ΔT) for R1, R2, and R3 samples, respectively, in accordance with an embodiment of the present disclosure.

With reference to FIGS. 6A-6C, a comparison of the rise in temperature of the R1, R2 and R3 devices when biased at a drain current I_{D} of 700mA/mm and V_{DS} = 28 V, which estimates a thermal reliability of the samples is depicted. The R2 device shows a considerably less rise in the temperature compared to the R1 device and is almost similar to the R3 device. This indicates the potential of AlₓTiₓO_{y} in suppressing self-heating in the GaN RF HEMTs. The comparison of maximum temperature rise (ΔT) at V_{DS} = 28 V and I_{D} = 700 mA/mm under 1 μs pulse width for the R1, R2 and R3 samples is shown. R1 showed ΔT of 117 °C, in R2, ΔT = 43 ° C while as ΔT = 33 ° C for R3.

FIGS. 7A-7B illustrate graphical representations depicting comparison of large signal characteristics at 10 GHz of R1 and R2 devices, respectively, in accordance with an embodiment of the present disclosure.

With reference to FIGS. 7A-7B, a comparison of large signal characteristics at 10 GHz of the R1 and R2 devices is depicted. FIG. 7A illustrates a comparison of an output power (Pout) and a gain (GP) of the R1 and R2 devices, and FIG. 7B illustrates a comparison of power added efficiency (PAE) of the R1 and R2 devices, where R2 is superior to R1 and almost similar to that of R3. R2 shows superior characteristics compared to the R1 and is comparable with R3 with 2.82 W/mm saturated output power at a PAE of 31 %.

Therefore, the proposed RF HEMT (200) allows for high power operation for commercial and defense applications and device scalability by increasing the breakdown voltage and suppressing self-heating without expanding the device's dimensions. Due to reliability issues such as current collapse and self-heating that hamper GaN-on-Si RF technology, a straightforward yet efficient technique for resolving these issues through p-type semiconductor passivation further propels this technology to a larger market share in the RF semiconductor sector by competing with the more expensive GaN-on-SiC RF technology.

Further, the p-type passivation underlapping the contact of the source and the drain efficiently engineers the channel electric field in the GaN RF HEMT technology. The resultant p-type passivation results in improved device DC, thermal, and RF performance in terms of lower leakage currents and higher OFF-state device breakdown voltage, along with improved device reliability in terms of reduced current collapse, self-heating, and improved large signal characteristics.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter is to be implemented merely as illustrative of the disclosure and not as a limitation.

### ADVANTAGES OF THE PRESENT DISCLOSURE

The present disclosure described herein above provides certain technical advancements over the existing prior art including, but not limited to:

The present disclosure provides a p-type passivation layer for Gallium Nitride (GaN)-based Radio Frequency (RF) High-Electron-Mobility Transistors (HEMTs) for enhanced performance and improved device reliability.

The present disclosure provides a p-type passivation layer that improves Direct Current (DC) characteristics, current collapse behavior, breakdown voltage, and large signal characteristics of the RF HEMTs.

The present disclosure uses a p-type semiconductor as passivation and gate-dielectric to reduce off-state leakage characteristics compared to conventional Silicon Nitride (SiN) passivation and gate dielectric.

The present disclosure provides a p-type passivation layer that suppresses self-heating considerably, enabling improved output power, gain, and power added efficiency.

The present disclosure provides a p-type passivation layer that efficiently distributes channel electric field in a gate-drain access region by suppressing an electric field peak near gate edge/field plate edge, which is a root cause of reliability issues in the RF HEMTs.

We claim:

1. A Radio Frequency (RF) High-Electron-Mobility Transistor (HEMT) (200) comprising:
a Gallium Nitride (GaN) layer (202) formed on a substrate (214);
a source (204a), a drain (204b), and a gate (204c) configured on the GaN layer (202); and
a passivation layer (206) comprising at least a p-type semiconductor (206a) disposed over the GaN layer (202), wherein the passivation layer (206) is configured to distribute channel electric field in a gate-drain access region of the RF HEMT (200), to reduce self-heating effect in the RF HEMT (200).

2. The RF HEMT (200) as claimed in claim 1, wherein the p-type semiconductor (206a) is disposed overlapping or underlapping a contact of the source (204a) and the drain (204b).

3. The RF HEMT (200) as claimed in claim 1, wherein the p-type semiconductor (206a) is deposited directly as a gate dielectric over a barrier region (208) or any other passivation layer, and wherein the barrier region (208) is formed over the substrate (214).

4. The RF HEMT (200) as claimed in claim 1, wherein the p-type semiconductor (206a) is deposited only as a passivation material and not present under a contact of the gate (204c).

5. The RF HEMT (200) as claimed in claim 1, wherein the p-type semiconductor (206a) is deposited towards the gate-drain access region.

6. The RF HEMT (200) as claimed in claim 1, wherein the p-type semiconductor (206a) is deposited under a contact of the gate (204c) or a field plate of the RF HEMT (200).

7. The RF HEMT (200) as claimed in claim 1, wherein the passivation layer (206) is configured to enhance performance and reliability of the RF HEMT (200) by distributing the channel electric field in the gate-drain access region.

8. The RF HEMT (200) as claimed in claim 1, wherein the passivation layer (206) is configured to enhance signal characteristics of the RF HEMT (200) due to the reduction in the self-heating effect in the RF HEMT (200).

9. The RF HEMT (200) as claimed in claim 1, wherein the passivation layer (206) is configured to minimize current collapse during a high-frequency operation, and increase a breakdown voltage of the RF HEMT (200).

10. The RF HEMT (200) as claimed in claim 1, wherein the p-type semiconductor (206a) is any or a combination of a nickel oxide, a p-GaN, a copper oxide, and an aluminium titanium oxide.

11. The RF HEMT (200) as claimed in claim 1, wherein the RF HEMT (200) is manufactured with or without a buffer region (212) over the substrate (214).

12. The RF HEMT (200) as claimed in claim 11, wherein the buffer region (212) is formed of at least one type of: a carbon-doped buffer, an iron-doped buffer, or a carbon and iron co-doped buffer.

13. The RF HEMT (200) as claimed in claim 1, wherein the RF HEMT (200) is configured with at least one of: one or more barriers and one or more back barriers, and wherein the one or more barriers is formed of at least one of: Aluminum Nitride (AlN), graded Aluminum Gallium Nitride (AlGaN), and Gallium Nitride (GaN) cap.

14. The RF HEMT (200) as claimed in claim 1, wherein the passivation layer (206) is configured with any gradient and stoichiometry based on a requirement.
